(19) United States
(12) Patent Application Publication
(10) Pub. No.: US 2014/0188264 A1
(43) Pub. Date: Jul. 3, 2014

(54) Workflow Manager and Bar Coding System for Processing of Samples/Substrates in HPC (High Productivity Combinatorial) R&D Environment

(71) Applicant: Intermolecular, Inc., San Jose, CA (US)

(72) Inventors: Harikrishanan Rajagopal, Sunnyvale, CA (US); Yoshiki E. Ashizawa, Pleasanton, CA (US); Joseph M. Jackson, San Jose, CA (US); Sandeep Mariserla, Danbury, CT (US); Heng Cheng Pai, Cupertino, CA (US); Radha Subrahmanyan, San Jose, CA (US); Karen Yang, Fremont, CA (US)

(73) Assignee: INTERMOLECULAR, INC., San Jose, CA (US)

(21) Appl. No.: 13/727,896

(22) Filed: Dec. 27, 2012

(51) Int. Cl. H01L 21/66

(52) U.S. Cl. CPC H01L 22/20
USPC 700/121

(57) ABSTRACT

Methods of semiconductor processing are described. An experiment is designed for each process of a semiconductor substrate, which are implemented on respective multiple regions of the semiconductor substrate. A unique identifier is assigned to the semiconductor substrate. The respective design of experiment is implemented for each of the processes of the semiconductor substrate. Process criteria for each process is recorded, where the recording is associated with the assigned unique identifier. Process information is retrieved for each process, via its respective assigned unique identifier.

### BACKGROUND

Wafer processing involves several steps, which may include multiple workstations and multiple operators or technicians. When a wafer is diced or separated into multiple coupons or chips, each diced coupon or chip may also undergo several processing steps, which may include multiple workstations and multiple operators. In addition, during research experiments on a coupon or substrate through combinatorial processing techniques, the coupon or substrate may be exposed to multiple processes that require exposure to multiple processing tools and characterization using metrology tools. Tracking each variable for a conventional or combinatorial process work flow becomes more difficult as the substrate or coupon proceeds through the process flow.

Methods of recording each variable of each processing step has been achieved using handwritten logs and/or using computerized plots or spreadsheets. However, manually recording each variable for each processing step for each coupon or substrate is very labor intensive and is prone to human errors and omissions. Therefore, there is a need in the art for a solution which overcomes these drawbacks.

### SUMMARY

In some embodiments, methods of managing semiconductor workflow are described. A unique wafer tracking identifier is assigned to a semiconductor substrate. Multiple regions of the semiconductor substrate are independently processed in a combinatorial manner. The semiconductor substrate is tracked during any stage of the independent processing, via the unique wafer tracking identifier. In some embodiments, the method is embodied as program instructions on a computer readable medium.

In some embodiments, a method of identifying and tracking semiconductor processing is described. An experiment is designed for each process of a semiconductor substrate, which are independently implemented on respective multiple regions of the semiconductor substrate. A unique identifier is assigned to the semiconductor substrate. The respective design of experiment is implemented for each of the processes of the semiconductor substrate. Process criteria for each process is recorded, where the recording is associated with the assigned unique identifier. Process information is retrieved for each process, via respective assigned unique identifier.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 is a schematic diagram, which illustrates an implementation of combinatorial processing and evaluation according to some embodiments.

FIG. 2 is a schematic diagram of a combinatorial system according to some embodiments.

FIG. 3 is a top view of a substrate according to some embodiments.

FIG. 4 is a schematic diagram illustrating a general methodology for combinatorial process sequence integration according to some embodiments.

FIG. 5 is a block diagram of an exemplary workflow manager and bar coding system according to some embodiments.

FIG. 6 is an illustration of a screenshot for a wafer being processed according to some embodiments.

FIGS. 7A-7B are screenshots illustrating combinatorial processing according to embodiments of the invention.

FIG. 8 is a flowchart for a method of managing semiconductor workflow according to embodiments of the invention.

FIG. 9 is a flowchart for a method of identifying and tracking semiconductor processing according to some embodiments.

FIG. 10 is a simplified schematic diagram of a screen shot enabling the tracking of a semiconductor substrate separated or cleaved into multiple substrates in accordance with some embodiments.

FIG. 11 is a screen shot enabling a user to enter further data when electing to cleave a substrate in accordance with some embodiments.

FIGS. 12A and 12B are screenshots of informatics modules illustrating the processing conditions in accordance with some embodiments.

FIGS. 13A and 13B are illustrations of a mobile workflow manager in accordance with some embodiments.

### DETAILED DESCRIPTION

Semiconductor manufacturing may include a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization, and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices, such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration,” on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing, such as etching and cleaning. HPC processing techniques have also been successfully adapted to deposition processes, such as physical vapor deposition (PVD), atomic layer deposition (ALD), and chemical vapor deposition (CVD).

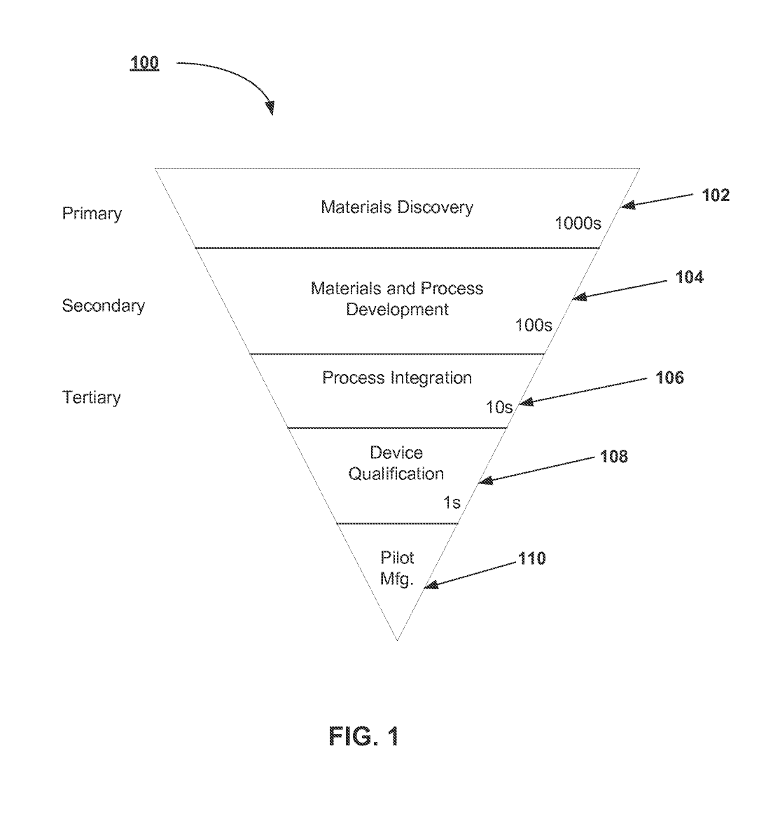

FIG. 1 is a schematic diagram 100, which illustrates an implementation of combinatorial processing and evaluation using primary, secondary, and tertiary screening. The schematic diagram 100 illustrates the relative number of combinatorial processes that run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage 102. Materials discovery stage 102 is also known as a primary screening stage, performed using primary screening techniques. Primary screening techniques may include dividing substrates into coupons and depositing materials using varied processes. The materials are then evaluated and promising candidates are advanced to the secondary screen, such as a materials and process development stage 104. Evaluation of the materials is performed using metrology tools such as electronic testers and imaging tools, e.g. microscopes.

The materials and process development stage 104 may evaluate hundreds of materials (i.e., a magnitude smaller than the primary stage) and may focus on the processes used to deposit or develop those materials. Promising materials and processes are again selected and advanced to the tertiary screen, such as a process integration stage 106, where tens of materials and/or processes and combinations are evaluated. The tertiary screen or process integration stage 106 may focus on integrating the selected processes and materials with other processes and materials.

The most promising materials and processes from the tertiary screen are advanced to device qualification stage 108. In device qualification stage 108, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing stage 110.

The schematic diagram 100 is an example of various techniques that may be used to evaluate and select materials and processes for the development of new materials and processes. The descriptions of primary, secondary, etc. screening and the various stages, 102-110 are arbitrary and the stages may overlap, occur out of sequence, or be described and performed in many other ways.

The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than just considering a series of local optimums, i.e., where the best conditions and materials for each manufacturing unit operation is considered in isolation, the embodiments described herein consider interaction effects introduced due to the multitude of processing operations that are performed and the order in which such multitude of processing operations are performed when fabricating a device. A global optimum sequence order is therefore derived and as part of this derivation, the unit processes, unit process parameters, and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate, which are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants, and location of structures within each region are designed to enable valid statistical analysis of the test results within each region and across regions to be performed.

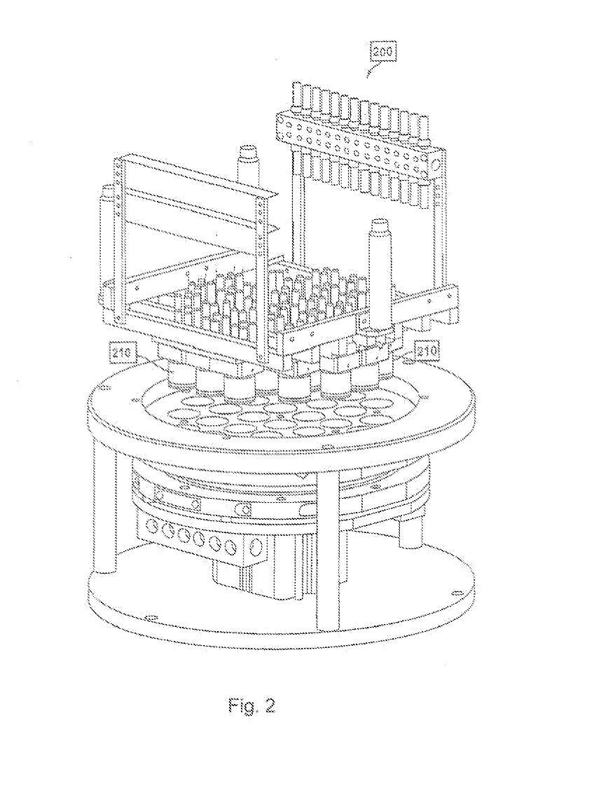

FIG. 2 is a schematic diagram of a combinatorial system 200, which may incorporate wet processing experiments or semiconductor manufacturing process sequences and unit operations in order to combinatorially evaluate various semiconductor manufacturing processes, such that an optimum process may be found in a minimum amount of time, in accordance with embodiments of the invention. System 200 includes a plurality of flow cells 210 which may be modular in design in order to efficiently evaluate a plurality of processes and utilize the same tool on various programs addressing customer specific problems. Such a system enables the use of customer specific wafers without requiring re-tooling. In some embodiments, twenty-eight flow cells are provided for twenty-eight discrete regions of a 12-inch wafer. It should be appreciated that this is not meant to be limiting, as any number of flow cells may be accommodated for any size wafer in a system. The number of flow cells will depend upon various factors, including the size and shape of the substrate being evaluated, the size of the regions on the substrate, etc. A rail system enabling flow cells 210 to be tailored to any pitch (e.g., spacing) of regions is provided. A flexible reactor based system may be used, as well as a static manifold system. System 200 includes a plurality of connections (not shown for illustrative purposes) distributed to each of flow cells 210. The facilities connections remain intact, while the process module can be replaced with an alternative process module and mated with the facilities module through kinematic coupling in some embodiments.

The system 200 of FIG. 2 may be connected to various inputs that may be affixed to system 200 through racks or external to system 200. Exemplary inputs include a dispense manifold to dispense any process fluids utilized in the system, a mix vessel for optionally mixing fluids prior to delivery to system 200, and any required power and gas inputs to operate the system. In addition, a waste collection mechanism may be in communication to receive process fluids evacuated from the reaction chambers or bypassed through flow cells 210.

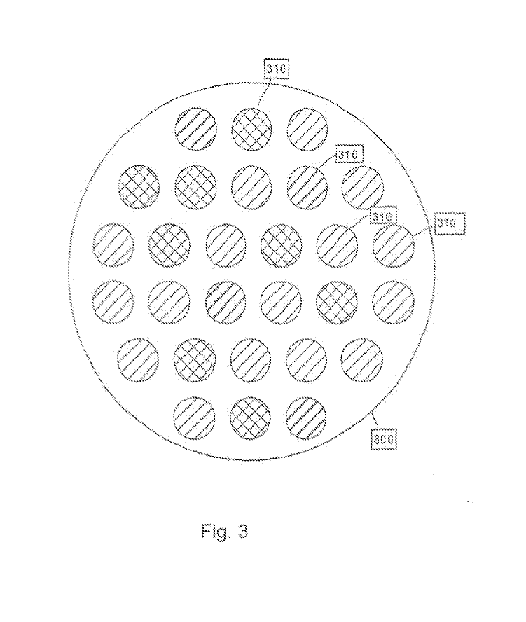

FIG. 3 is a top view of a substrate 300 having regions processed differently through the modular head system described herein in accordance with an embodiment of the invention. Substrate 300 has a plurality of regions 310, which have been combinatorially processed. Twenty-eight regions are provided on substrate 300 in this exemplary embodiment. More or fewer regions can be defined in alternative embodiments. It should be appreciated that on substrate 300, a vast amount of knowledge exists on a single substrate, as each of regions 310 may have some property or characteristic of the process altered. Thus, the information available for each region, as well as the interaction of each region with previous or subsequent process operations or materials, may be harvested to provide data on an optimum material, unit process, and/or process sequence in a highly efficient manner. While FIG. 3 illustrates regions 310 as isolated and not overlapping, the regions may overlap in some embodiments. In other embodiments, a region refers to a localized area on a substrate which is, was, or is intended to be used for processing or formation of a selected material. The region can include one region and/or a series of regular or periodic regions pre-formed on the substrate 300. The region may have any convenient shape, e.g., circular, rectangular, elliptical, wedge-shaped, etc. In an embodiment, regions 310 are predefined on the substrate 300. However, the processing may define the regions 310 in some embodiments. In some embodiments, substrate 300 has a custom identifier affixed to a surface of the substrate. As explained below, the custom identifier may take the form of a bar code in some embodiments.

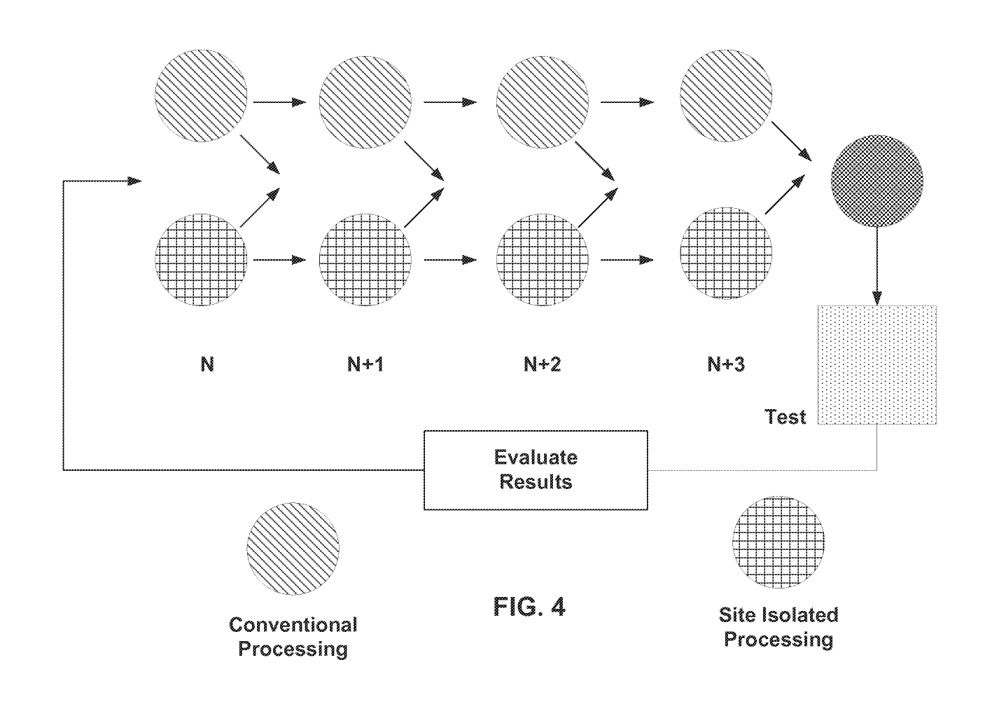

FIG. 4 is a simplified schematic diagram illustrating a general methodology for combinatorial process sequence integration that includes site isolated processing and/or conventional processing in accordance with an embodiment of the invention. The substrate is initially processed using conventional process N. In an exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed, such that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 4. For instance, the combinatorial process sequence integration can be applied to any desired segments and/or portions of an overall process flow. Characterization, including physical, chemical, acoustic, magnetic, electrical, optical, etc. testing can be performed after each process operation and/or series of process operations within the process flow, as desired. The feedback provided by the testing is used to select certain materials, processes, process conditions, and process sequences and eliminate others. Furthermore, the above flows can be applied to entire monolithic substrates or portions of monolithic substrates, such as coupons.

Under combinatorial processing operations, the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and are not meant to be an exhaustive list, as other process parameters used in semiconductor manufacturing may be varied.

As mentioned above, within a region, the process conditions are substantially uniform, in contrast to gradient processing techniques which rely on the inherent non-uniformity of the material deposition. That is, the embodiments described herein may locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and therefore, non-overlapping. When the regions are adjacent, there may be a slight overlap wherein the materials or precise process interactions are not known; however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

Methods for monitoring and tracking semiconductor processing, such as cleaning, surface preparation, deposition, patterning, etching, thermal annealing, and any other processing operation from the original wafer to each of the final diced coupons are described. Process variables, such as materials, environmental conditions, operating set points, equipment, operator, time, priority, changes made, and errors encountered are recorded for each wafer, coupon, or substrate at each level of processing.

Embodiments of the invention enable a process user to define a workflow sequence without any restriction on the number of steps, experimental conditions, type and number of HPC tools, etc. Substrate identifiers are created automatically for each substrate, enabling the user to track the progress of the processing of the substrate from a central location. Enhanced data integrity is provided, as controls are in place for revision and updating of the file. Opening multiple file copies at the same time is avoided.

A custom identifier is associated with each wafer, coupon, or substrate, and the custom identifier remains with its associated wafer, coupon, or substrate throughout all stages of processing. The recorded process variables pertain to actual real-time processing, as well as processing to be carried out for each sample at each level of processing. Any stage of the processing for any level can be tracked, via unique tracking identifiers for each sample or group of samples processed together.

In some embodiments, custom identifiers enable tracking even if an initial wafer or substrate is separated or diced. An initial wafer or substrate may have a custom identifier, such as a two-dimensional or three-dimensional bar code, assigned thereto. At a later stage of processing, the wafer may be separated into a plurality of coupons. Each coupon may have the parent wafer custom identifier, in addition to a unique coupon identifier. The format of each divided coupon identifier may be: parent#/coupon₁#, parent#/coupon₂#, parent#/coupon₃#, etc. Where the parent#/coupon₂# is further divided into multiple sub-coupons, each sub-coupon may have the parent wafer custom identifier and the coupon₂ custom identifier, in addition to a unique sub-coupon identifier. As a result, each sub-coupon may have the unique identifier format of: parent#/coupon₂#/sub-coupon₁#, parent#/coupon₂#/sub-coupon₂#, parent#/coupon₂#/sub-coupon₃#, etc. Any other formatting scheme that provides identification of an original sample with subsequent separation into multiple sub-samples is contemplated by the embodiments described herein.

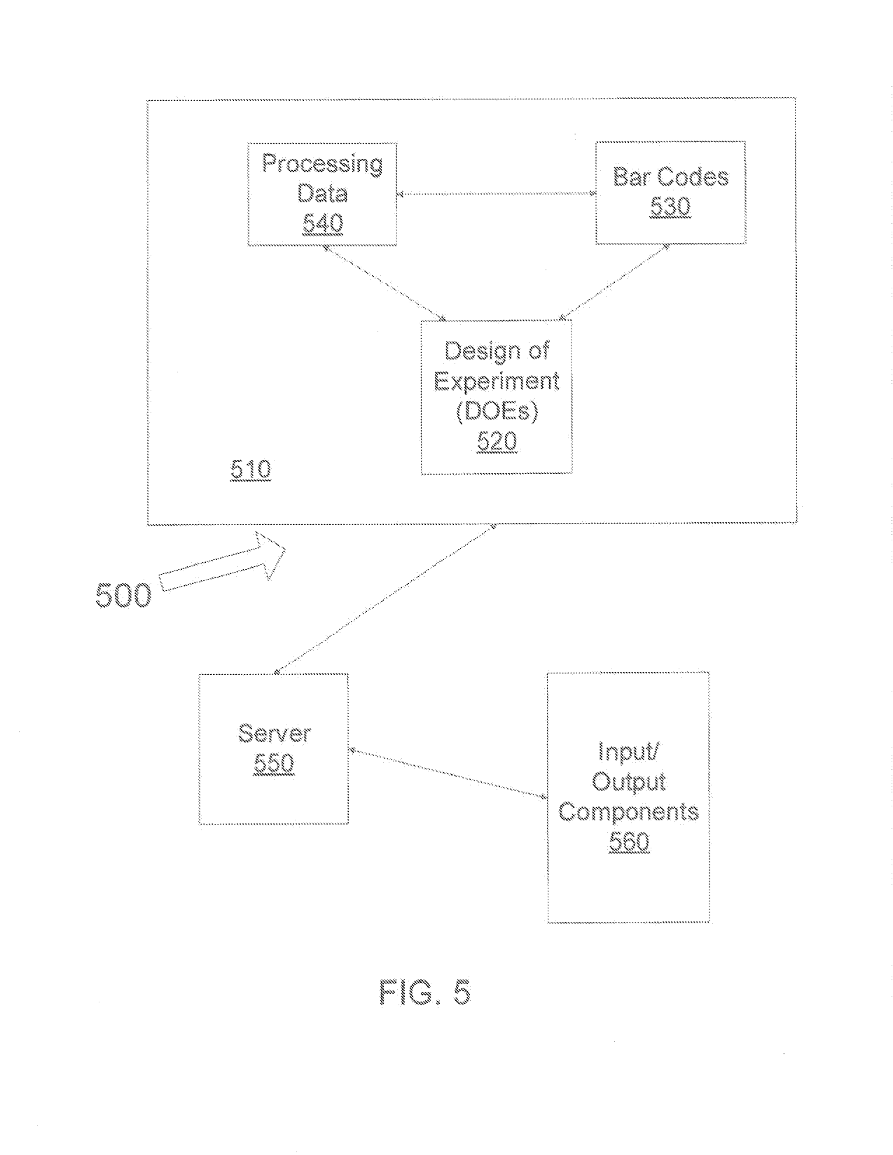

FIG. 5 is a block diagram of a workflow manager and bar coding system 500 according to some embodiments. A data warehouse 510 contains unstructured information and raw data, such as design of experiments, plans, lab notes, tool recipes, and results files. The data warehouse 510 also contains structured data, such as calculations, pivot tables, statistics, and tables of organized data. In addition, the data warehouse 510 contains data for analysis, reporting, and decision support, which may include charts, summaries, and web reports.

The data warehouse 510 comprises multiple modules, as illustrated in FIG. 5, which include a design of experiment (DOE) module 520, a bar code module 530, and a processing data module 540. Several other modules may be integrated into data warehouse 510 based on the application. It should be appreciated that each module may include software, hardware or some combination of the two, e.g., firmware. A DOE module 520 may contain all of the instructions and criteria, or recipes for each particular process of a semiconductor wafer, coupon, or substrate. The DOE module 520 is the initial planning stage for each process that is to be conducted on the semiconductor wafer, coupon, or substrate in some embodiments. Various semiconductor processes may include, but are not limited to cleaning, surface preparation, deposition, patterning, etching, thermal annealing, etc. The HPC processing of a wafer, coupon, or substrate requires process users to create a DOE for each sample or group of samples processed together, and to track the samples through multiple HPC processing steps and tools.

As an example of HPC processing using embodiments, a deposition DOE may contain step-by-step instructions for depositing a dielectric layer on a semiconductor sample or region of the semiconductor sample, as well as criteria for the raw materials used, the method of deposition, and all operating temperatures and conditions. Additional DOEs would be created for each deposition layer for the semiconductor sample and/or region of the semiconductor sample. One or more DOEs would also be created for each of the other processes for the semiconductor wafer, coupon, or substrate, i.e., cleaning, surface preparation, patterning, etching, thermal annealing, etc. The individual DOEs may be stored in the DOE module 520.

A unique bar code or custom identifier is assigned to each wafer or substrate and the identifier is stored in the bar code module 530. Any bar-coding system could be utilized for assigning a unique bar code, such as a two-dimensional bar code or a three-dimensional bar code. Some embodiments use a three-dimensional bar code, since much more information can be associated with a three-dimensional bar code. The unique bar code assigned to each semiconductor sample remains with the particular semiconductor sample from the start of processing through final processing. The unique bar code can be produced via an input/output component 560, such as a scanner having label output generation. The unique bar code label can be physically associated with a sample or group of samples in various ways, such as affixing the label to the individual samples or a container in which multiple group processed samples are held. The unique bar code can also be associated with a sample or group of samples through other means, such as laser marking, etching, etc.

The resulting data associated with each stage of processing a semiconductor sample is stored in the processing data module 540. Processing criteria include, but are not limited to materials, equipment, operator, time, priority, changes made, errors encountered, etc. The processing criteria can be the same or can vary for each DOE and the DOE can have variables or parameters varied between regions of the semiconductor sample being processed. The DOE module 520, the bar code module 530, and the processing data module 540 of the data warehouse 510 are all interconnected, such as through multiple software pointers in some embodiments.

A semiconductor wafer, coupon, or substrate is processed through multiple stages, such as the stages of cleaning, surface preparation, deposition, patterning, etching, thermal annealing, etc. When a semiconductor sample enters a processing stage, the unique bar code is scanned, i.e., read by an input/output component 560. The unique bar code can be scanned using a combination of a device capable of recognizing the particular two-dimensional or three-dimensional bar code and associated software. All data that has been recorded up to that point has been stored in the processing data module 540 and can be accessed by scanning the bar code. The processing of scanning and data retrieval is controlled by a server 550, such as a relational database management system in some embodiments.

The following example discusses an embodiment for illustrative purposes. If the semiconductor sample has entered the first stage of processing, then the DOE may be the only recorded data at that point. As the sample proceeds through the first stage of processing, all criteria relating to the first stage of processing is recorded, such as materials and equipment used, operator, time, priority, changes made from the DOE, and errors encountered, as well as any other relevant factors that should be noted. In some embodiments, the sample is scanned prior to each stage and at the conclusion of each stage, however, this is not meant to be limiting as the sample scanning points can be set based on a particular application. When the sample enters the second stage of processing, the unique bar code of the semiconductor sample is scanned again. All data pertaining to the DOE and the first stage of processing for that sample may be retrieved upon the second stage scanning Again, all criteria relating to the second stage of processing is recorded, which is associated with the same unique bar code for that particular sample. A similar process of scanning and recording continues for all processing stages for the particular semiconductor processed sample. When a sample or group of samples is completely processed, all processing data may be retrieved for the sample or group of samples by scanning its unique bar code. Some embodiments provide a filtering component to search for samples during processing, according to one or more particular processing criteria.

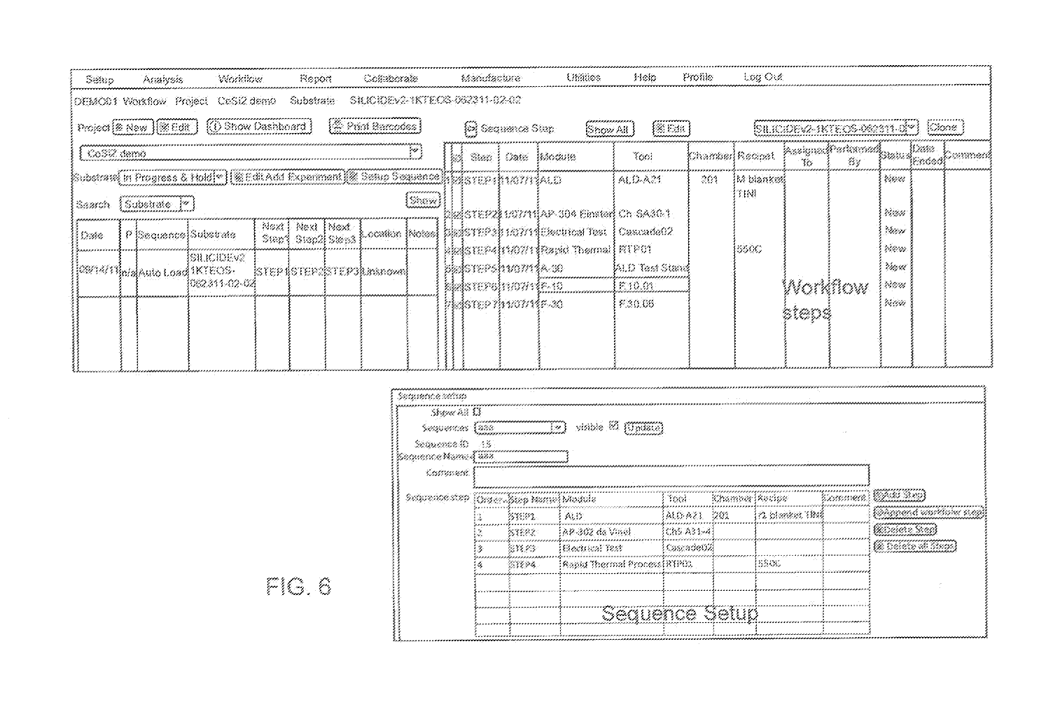

FIG. 6 is an illustration of a screenshot for a wafer being processed. As illustrated, the wafer is at the stage of depositing a silicide layer in this example. The top window of FIG. 6 illustrates various workflow steps that are taken for the silicide deposition. As illustrated in the top window, the workflow steps for each sequence step experienced by the substrate are captured. For example, with regard to step 6 of the top window, the date, module, tool, chamber, recipe, etc., are captured for the substrate being processed. In the top window, buttons and pull down menus associated with the generation and printing of the bar codes are illustrated. Additional buttons include the ability to clone or copy workflow sequences for additional substrates, as well as search, filter, update and track workflow execution status. Comment fields are provided to enable a user to enter comments and provide for disposition of substrates for Quality Assurance purposes in some embodiments. The lower window illustrates the sequence setup. In the lower window, the sequence setup provided is a commonly used sequence and therefore saved so that a user can call up the sequence without the need to enter all the necessary data for the sequence. For example, steps 1-4 are listed as a saved sequence setup so that the user can call up this sequence when designing an experiment for the substrate.

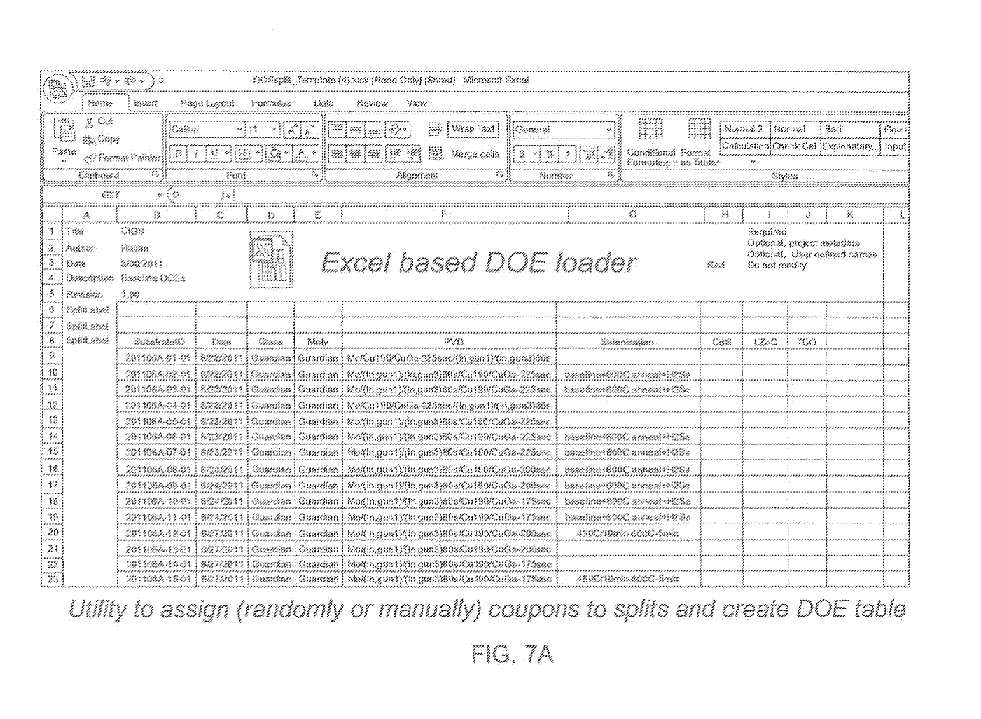

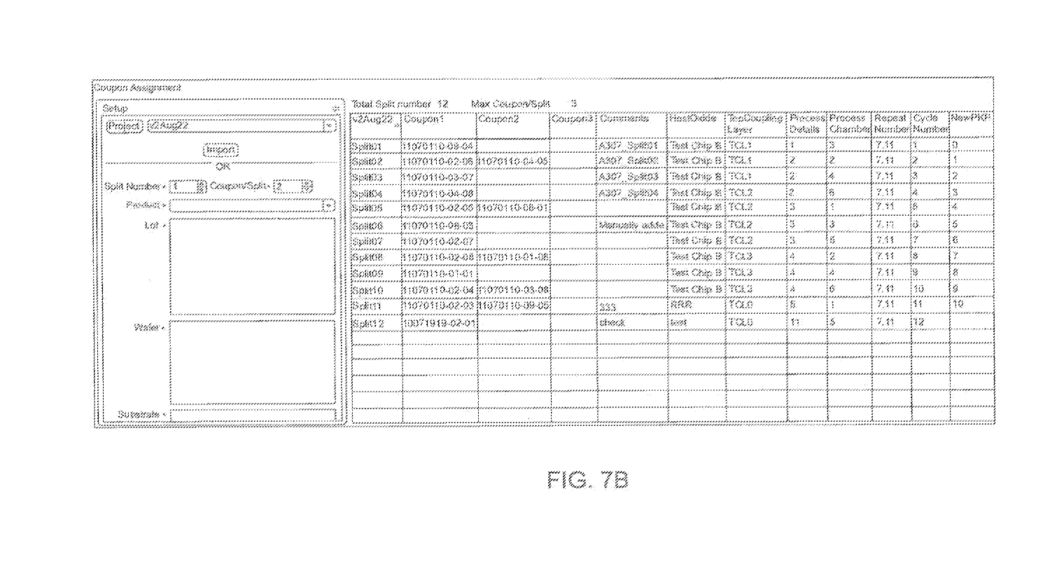

FIG. 7A is a screenshot illustrating a DOE table, where batch processing is listed for multiple substrates each having a unique identifier. In FIG. 7A multiple DOEs are provided for multiple substrates in a spreadsheet format. The data from the spreadsheet may be uploaded into the system of FIG. 5 and the screenshot of FIG. 6 is generated for each substrate ID of FIG. 7A in some embodiments. FIG. 7B is a screenshot illustrating coupon assignments where the coupons are grouped according to the processing and/or tools that perform the processing. For example, Split01 provides three coupons, Coupon1, Coupon2, and Coupon3 that are each processed in the same tool with the same recipe. FIG. 7B is an example of a view of the substrates being processed according to the process tool/recipe.

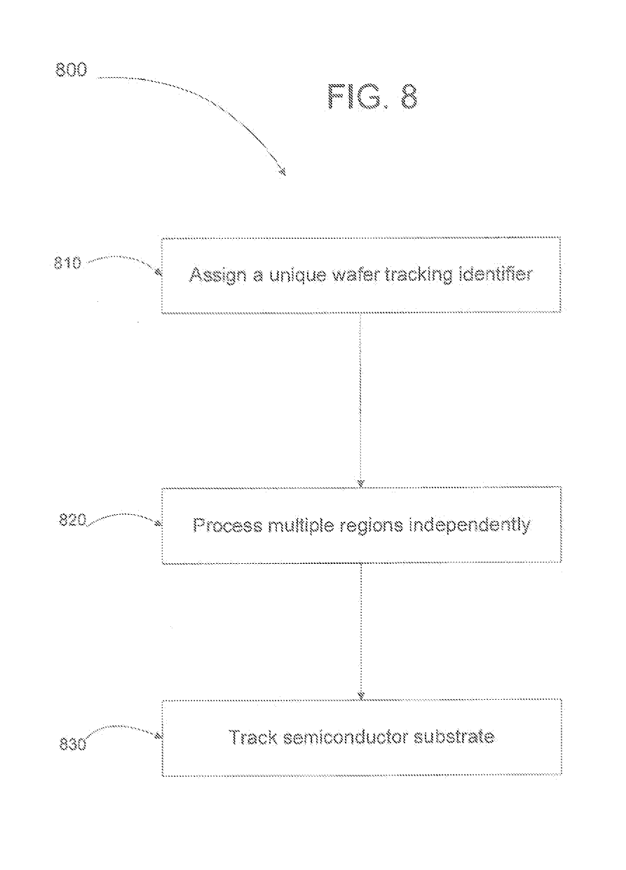

FIG. 8 is a flowchart illustrating a method of processing a semiconductor 600 according to embodiments of the invention. A unique wafer tracking identifier is assigned to a semiconductor substrate in step 810. The unique identifier may be generated through the system described above with reference to FIGS. 5 and 6 in some embodiments. It should be appreciated a combinatorial processing sequence may be associated with the unique wafer tracking identifier as illustrated with reference to FIG. 6. The semiconductor substrate is processed across multiple regions in a combinatorial manner in step 820, where the processing may differ across the multiple regions. It should be appreciated that the processing may occur in series or in parallel across the multiple regions. The combinatorial processing may be implemented according to one or more embodiments described above with reference to FIGS. 1-4. The processing may include one or more of cleaning, surface preparation, deposition, patterning, etching, thermal annealing, etc. The semiconductor substrate is processed according to a plurality of wafer processing variables, which may be previously established as a design of experiment, or recipe. The processing variables may include one or more of materials, environmental conditions, operating set points, equipment, operator, time, priority, changes made, errors encountered, etc. Tracking of the semiconductor substrate during any stage of the independent processing occurs in step 830. The tracking is executed via the unique wafer tracking identifier. An additional embodiment of the method of managing semiconductor workflow 800 includes separating the semiconductor substrate into a plurality of coupons and assigning associated unique coupon tracking identifiers. Each unique coupon tracking identifier comprises processing instructions to be implemented for each associated coupon of the plurality of coupons and is linked to the parent coupon.

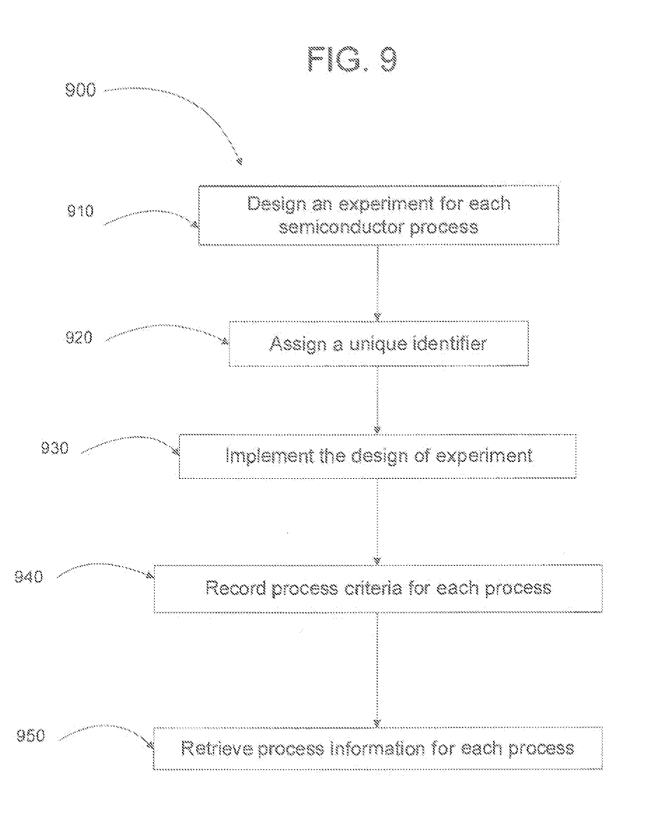

FIG. 9 is a flowchart illustrating a method of identifying and tracking semiconductor processing 900 according to embodiments of the invention. An experiment is designed for each process for a semiconductor substrate in step 910. The processes may include one or more of cleaning, surface preparation, deposition, patterning, etching, thermal annealing, etc. A unique identifier is assigned to the semiconductor substrate in step 920. The unique identifier may be one of a two-dimensional or three-dimensional bar code in some embodiments. The experiment is implemented in step 930 for each of the processes. The processes are independently and/or simultaneously implemented on respective multiple regions of the semiconductor substrate in a combinatorial manner in some embodiments. Different processes may simultaneously occur across the multiple regions of the semiconductor substrate in some embodiments. Process criteria for each process is recorded, where the recording is associated with the assigned unique identifier in step 940. Process criteria may comprise one or more of materials, environmental conditions, operating set points, equipment, operator, time, priority, changes made, and errors encountered. Process information, which includes the recorded process criteria, is retrieved for each of the processes in step 950 via the respective assigned unique identifier in order for a user to view the process history for the regions of the substrate.

An additional embodiment of the method of identifying and tracking semiconductor processing 900 includes separating the semiconductor substrate into multiple coupons. Each coupon comprises multiple discrete regions, which may be processed independently in a combinatorial manner, according to one or more embodiments described above. A unique identifier is assigned to each coupon. A status of each of the coupons may be tracked via their respective assigned unique identifiers. The status of workflow execution or data capture can be tracked and is accessible to a user through the embodiments described herein. It should be appreciated that the instructions for each flowchart of FIGS. 8 and 9 may be embodied as program instructions on a non-transient computer readable medium and executed through a processor in some embodiments.

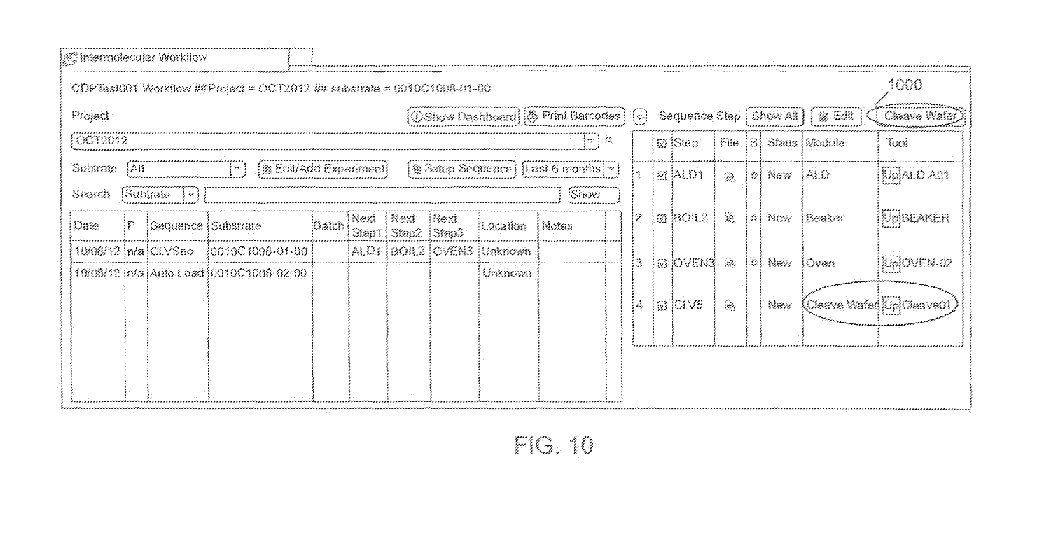

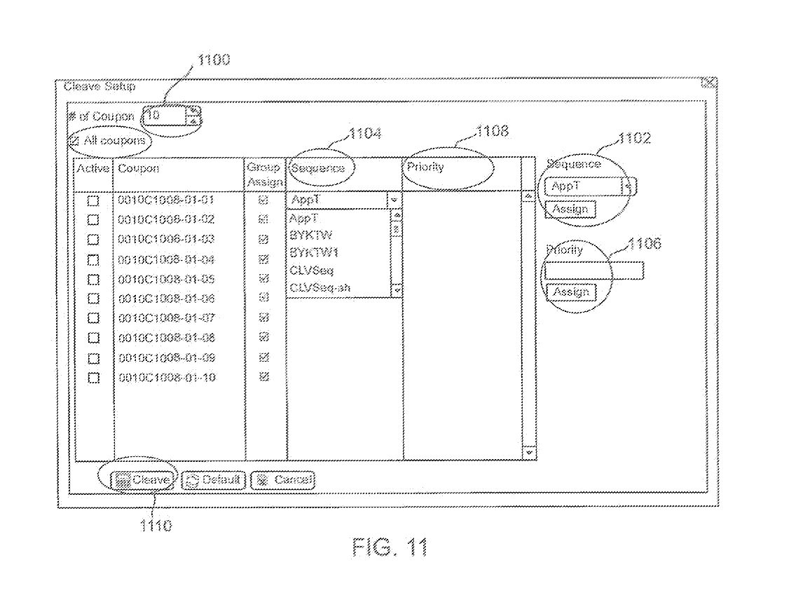

FIG. 10 is a simplified schematic diagram of a screen shot enabling the tracking of a semiconductor substrate separated or cleaved into multiple substrates in accordance with some embodiments. In the screen shot of FIG. 10, cleave wafer button 1000 enables the functionality to continue to track substrates cleaved from a parent substrate. Activating button 1000 results in a cleave setup screen illustrated in screen shot illustrated in FIG. 11. The screen shot of FIG. 11 enables a user to enter a number of coupons to create in box 1100, which is illustrated as 10 in this example. The user may activate or in-activate individual coupons using the Active checkbox along the left hand side of FIG. 11 (the substrates selected to be Active will be activated after the Cleave step for the parent wafer is completed in some embodiments). A user can select the sequence assignment for each separated coupon/substrate. It should be appreciated that the sequence assignment can be done via a batch assignment using the Sequence drop-down and Assign button 1102, or individual sequence for each coupon using the drop down sequence selections in the drop-down menu 1104. A priority for each coupon, either as a batch assignment using the Priority text box and Assign button 1106 or individual text input for each coupon row of column 1108, is provided. Once cleave button 1110 is activated the selections are captured and the data is uploaded into the workflow management system described herein. In some embodiments, additional steps may be provided to activate the separated coupons in the system upon completion of the setup described with regard to FIGS. 10 and 11.

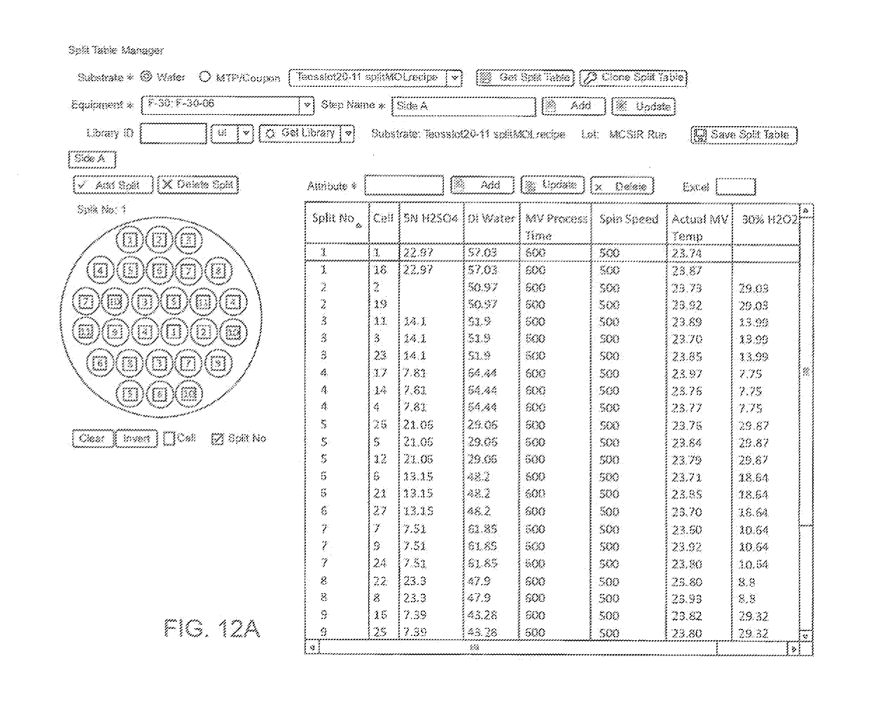

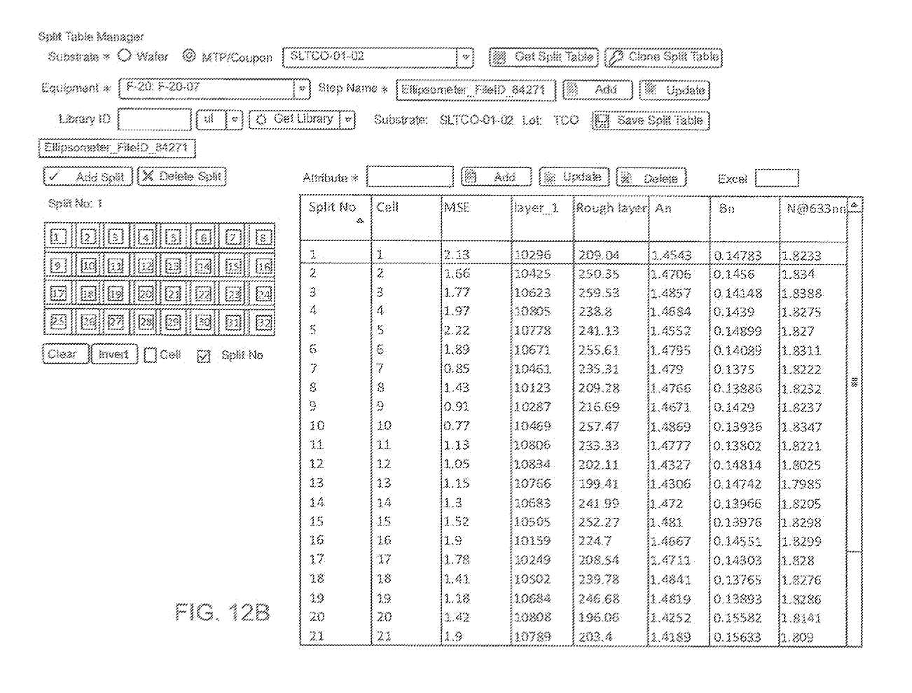

FIGS. 12A and 12B are screenshots of informatics modules illustrating the processing conditions in accordance with some embodiments. In FIG. 12A the screenshot illustrates the different regions of a circular substrate. The processing conditions for each region are captured in the table adjacent to the substrate illustration. The split number column illustrates regions having similar processing conditions and the cell column of the table contains the sequential region number. Thus for the illustration provided for FIG. 12A there were 11 splits utilized with cell numbers 1 and 18 processed under the conditions for split number 1, and so on. The remaining columns contain the conditions for the DOE for that particular split/cell number. In FIG. 12B a rectangular coupon having 32 regions is illustrated. In this example, the 32 regions are processed differently and consequently the split number and cell number columns of the associated table are identical. The remaining columns of the table provide the processing conditions for the DOE so that the conditions for each of the experiments can be captured and saved. Thus, each of the combinatorial experiments is tracked according to the substrate/coupon identifier in accordance with the screenshot illustrations of FIGS. 12A and 12B in some embodiments.

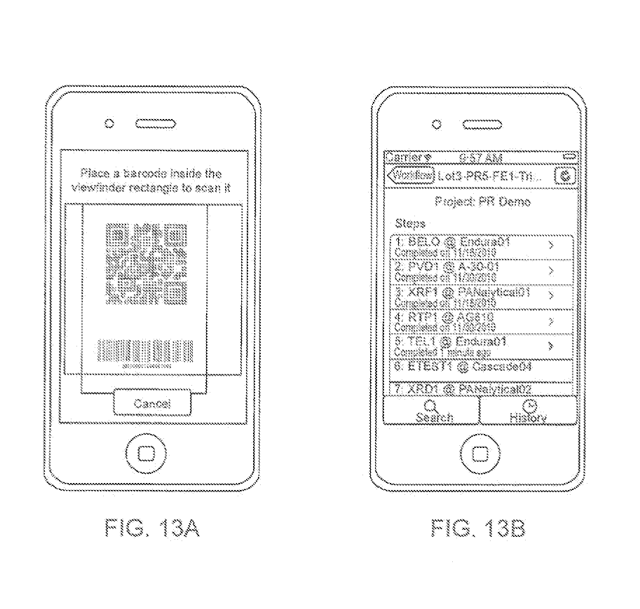

FIGS. 13A and 13B are illustrations of a mobile workflow manager interface in accordance with some embodiments. In FIG. 13A the bar code for the substrate/coupon is scanned through a mobile computing device in order to access the screenshot illustrated in FIG. 13B. In this manner, the data recorded through the embodiments described herein is readily available through a mobile device in some embodiments. It should be appreciated that an application accessing the data from the system of FIG. 5 provides the desired interface to view the processing history as well as any future processing for a particular substrate.

Although the foregoing embodiments of the invention have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within the scope and equivalents of the appended claims. In the claims, elements and/or steps do not imply any particular order of operation, unless explicitly stated in the claims.

What is claimed is:

1. A method of processing a semiconductor, the method comprising:
assigning a unique identifier to a semiconductor substrate;
associating a combinatorial processing sequence with the unique identifier;
processing multiple regions of the semiconductor substrate in a combinatorial manner according to the combinatorial processing sequence; and
tracking the semiconductor substrate during any stage of the processing via the unique identifier.

2. The method of claim 1, wherein the combinatorial processing sequence comprises one or more of cleaning, surface preparation, deposition, patterning, etching, and thermal annealing.

3. The method of claim 1, wherein the independently processing differs across each of the multiple regions and wherein the unique wafer tracking identifier maintains a history for each of the multiple regions.

4. The method of claim 1, wherein the wafer processing variables comprise one or more of materials, environmental conditions, operating set points, equipment, operator, time, priority, changes made, and errors encountered.

5. The method of claim 1, further comprising:
separating the semiconductor substrate into a plurality of coupons; and
assigning a plurality of respective unique coupon tracking identifiers for each of the plurality of coupons.

6. The method of claim 5, wherein each of the unique coupon tracking identifiers is associated with processing instructions to be implemented for each respective coupon of the plurality of coupons.

7. A non-transient computer readable medium having program instructions for processing a semiconductor, the computer readable medium comprising:
program instructions for assigning a unique identifier to a semiconductor substrate;
program instructions for associating a combinatorial processing sequence with the unique identifier;
program instructions for processing multiple regions of the semiconductor substrate in a combinatorial manner according to the combinatorial processing sequence; and
program instructions for tracking the semiconductor substrate during any stage of the processing via the unique identifier.

8. The computer readable medium of claim 7, wherein the processing differs across each of the multiple regions and wherein the unique wafer tracking identifier maintains a history for each of the multiple regions.

9. The computer readable medium of claim 7, further comprising:
program instructions for separating the semiconductor substrate into a plurality of coupons; and
program instructions for assigning a plurality of respective unique coupon tracking identifiers for each of the plurality of coupons.

10. The computer readable medium of claim 7, wherein the unique identifier is a bar code.

11. The computer readable medium of claim 7, wherein the multiple regions of the semiconductor substrate are isolated from each other during the processing.

12. The computer readable medium of claim 7, wherein the combinatorial processing sequence includes wafer processing variables comprising one or more of materials, environmental conditions, operating set points, equipment, operator, time, priority, changes made, and errors encountered.

13. A method of identifying and tracking semiconductor processing, the method comprising:
designing an experiment for each of a plurality of processes to be independently implemented on respective multiple regions of a semiconductor substrate;
assigning a unique identifier to the semiconductor substrate;
implementing the experiment for each of the plurality of processes;
recording process criteria for each of the plurality of processes associated with the assigned unique identifier; and
retrieving the recorded process criteria for each of the plurality of processes via respective assigned unique identifier for the semiconductor substrate.

14. The method of claim 13, wherein the implementing comprises simultaneously implementing the plurality of processes on respective multiple regions.

15. The method of claim 14, wherein the plurality of processes comprise different processes across the respective multiple regions of the semiconductor substrate.

16. The method of claim 13, wherein the plurality of processes comprises one or more of cleaning, surface preparation, deposition, patterning, etching, and thermal annealing.

17. The method of claim 13, wherein the process criteria comprises one or more of materials, environmental conditions, operating set points, equipment, operator, time, priority, changes made, and errors encountered.

18. The method of claim 13, further comprising:
separating the semiconductor substrate into a plurality of coupons;
assigning a unique identifier to each of the plurality of coupons; and
tracking a status of each of the plurality of coupons via respective assigned unique identifier for each of the plurality of coupons.

19. The method of claim 18, wherein assigning comprises:
affixing a bar code to one of the semiconductor substrate or a container holding the semiconductor substrate.

20. The method of claim 13, wherein the unique identifier is embodied as a bar code affixed to the semiconductor substrate.
